(19) United States
(12) Patent Application Publication
(10) Pub. No.: US 2026/0123192 A1
(43) Pub. Date: Apr. 30, 2026

(54) DISPLAY PANEL AND DISPLAY APPARATUS

(71) Applicant: Yungu (Gu’an) Technology Co., Ltd., Langfang (CN)

(72) Inventor: Junhui LOU, Langfang (CN)

(73) Assignee: Yungu (Gu’an) Technology Co., Ltd., Langfang (CN)

(21) Appl. No.: 19/432,187

(22) Filed: Dec. 24, 2025

Related U.S. Application Data
(63) Continuation of application No. PCT/CN2023/134171, filed on Nov. 24, 2023.

(30) Foreign Application Priority Data
Jun. 30, 2023 (CN) 202310793115.X

(51) Int. Cl. H10K 59/122; H10K 59/40

(52) U.S. Cl. CPC H10K 59/122; H10K 59/40

(57) ABSTRACT

Embodiments of the present application provide a display panel and a display apparatus. The display panel includes: a substrate; a pixel define layer arranged on the substrate, the pixel define layer including a pixel defining portion and pixel openings enclosed by the pixel defining portion; an isolation structure arranged on the substrate, the isolation structure including a conductive portion; and a functional layer including first electrodes and touch electrodes, where at least part of a corresponding one of the first electrodes is located within a corresponding one of the pixel openings, the touch electrodes are located on a side of the conductive portion away from the substrate, the first electrodes are insulated and spaced apart from the touch electrodes, the first electrodes are insulated and spaced apart from the conductive portion, and a corresponding one of the touch electrodes and the conductive portion are electrically connected to each other.

### CROSS-REFERENCE TO RELATED APPLICATIONS

The present application is a continuation application of International Application No. PCT/CN2023/134171, filed on November 24, 2023, which claims priority to Chinese Patent Application No. 202310793115.X, entitled "DISPLAY PANEL AND DISPLAY APPARATUS" and filed on June 30, 2023, which is incorporated herein by reference in its entirety.

### TECHNICAL FIELD

The present application relates to the technical field of display devices, and particularly to a display panel and a display apparatus.

### BACKGROUND

An organic light-emitting diode (OLED) is an active light-emitting device. Compared with a conventional liquid crystal display (LCD) method, OLED display technology does not require a backlight and has self-luminescence properties. The OLED uses a thin film layer of an organic material and a glass substrate. When a current passes through the film layer of the organic material, the organic material emits light. Therefore, OLED display panels can significantly save energy and be made lighter and thinner, tolerate a wider range of temperature changes than LCD display panels, and have a larger viewing angle. The OLED display panel technology is expected to become the next generation of flat panel display technology after LCD technology, and is one of the flat panel display technologies that have attracted most attention currently.

Existing OLED display devices include a touch module, which is usually of an add-on type. The add-on touch patch is attached to a surface of a display screen body, which leads to increased structural complexity and thickness of the display devices.

### SUMMARY

Embodiments of the present application provide a display panel and a display apparatus, with a view to simplifying the structure of the display panel.

An embodiment of a first aspect of the present application provides a display panel. The display panel includes: a substrate; a pixel define layer arranged on the substrate, the pixel define layer including a pixel defining portion and pixel openings enclosed by the pixel defining portion; an isolation structure arranged on the substrate, the isolation structure including a conductive portion; and a functional layer including first electrodes and touch electrodes, where at least part of a corresponding one of the first electrodes is located within a corresponding one of the pixel openings, the touch electrodes are located on a side of the conductive portion away from the substrate, the first electrodes are insulated and spaced apart from the touch electrodes, the first electrodes are insulated and spaced apart from the conductive portion, and a corresponding one of the touch electrodes and the conductive portion are electrically connected to each other.

An embodiment of a second aspect of the present application further provides a display apparatus, including a display panel according to any one of the above embodiments of the first aspect.

In the display panel according to this embodiment of the present application, the display panel includes a substrate, a pixel define layer, an isolation structure, and a functional layer. The pixel define layer includes a pixel defining portion and pixel openings, and a corresponding one of the pixel openings is used to arrange a light-emitting unit to implement the luminous display of the display panel. The functional layer includes first electrodes and touch electrodes, where at least part of a corresponding one of the first electrodes is located within a corresponding one of the pixel openings to drive the light-emitting unit to emit light. The touch electrodes are arranged on a conductive portion, such that the isolation structure can isolate the touch electrodes from the first electrodes, and the first electrodes and the touch electrodes are less prone to short-circuit connection. A corresponding one of the touch electrodes and the first conductive portion are electrically connected to each other, which can reduce the impedance of the touch electrode and improve the touch effect of the display panel. By arranging the touch electrodes and the first electrodes in the same functional layer, the present application can simplify the structure and preparation process of the display panel.

### BRIEF DESCRIPTION OF THE DRAWINGS

FIG. 1 is a schematic plan view of a display panel according to an embodiment of the present application;

FIG. 2 is a cross-sectional view along line A-A in FIG. 1;

FIG. 3 is a schematic plan view of a display panel according to another embodiment of the present application;

FIG. 4 is a cross-sectional view along line B-B in FIG. 3;

FIG. 5 is a cross-sectional view along line B-B in FIG. 3 according to another example;

FIG. 6 is a cross-sectional view along line B-B in FIG. 3 according to still another example;

FIG. 7 is a cross-sectional view along line B-B in FIG. 3 according to yet another example;

FIG. 8 is a cross-sectional view along line B-B in FIG. 3 according to yet another example;

FIG. 9 is a schematic partial structural diagram of a display panel according to still another embodiment of the present application;

FIG. 10 is a schematic partial structural diagram of a display panel according to yet another embodiment of the present application;

FIG. 11 is a schematic partial structural diagram of a display panel according to still yet another embodiment of the present application; and

FIG. 12 is a cross-sectional view along line B-B in FIG. 3 according to yet another example.

### DETAILED DESCRIPTION OF THE EMBODIMENTS

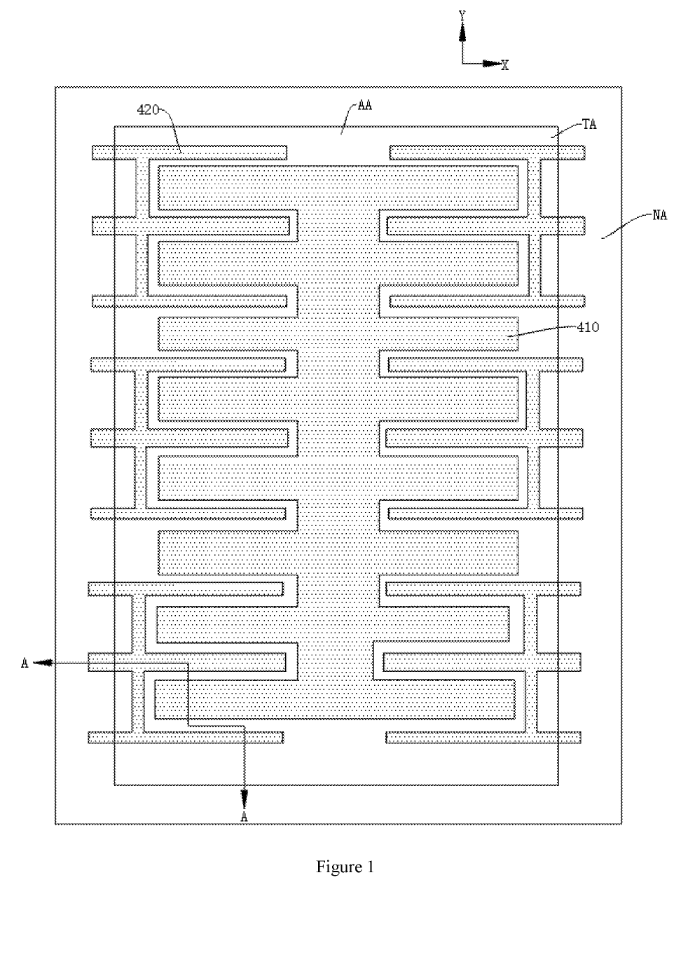

In order to better understand the present application, a display panel and a display apparatus according to the embodiments of the present application will be described in detail below with reference to FIGS. 1 to 12.

Referring to FIGS. 1 and 2 together, FIG. 1 is a schematic plan view of a display panel according to an embodiment of the present application; and FIG. 2 is a cross-sectional view along line A-A in FIG. 1.

As shown in FIGS. 1 and 2, an embodiment of the first aspect of the present application provides a display panel. The display panel includes a substrate 100, a pixel define layer 200, an isolation structure 300, and a functional layer 400. The pixel define layer 200 is arranged on the substrate 100. The pixel define layer 200 includes a pixel defining portion 210 and pixel openings 220 enclosed by the pixel defining portion 210. The isolation structure 300 is arranged on the substrate 100. The isolation structure 300 includes a conductive portion 310. The functional layer 400 includes first electrodes 410 and touch electrodes 420. At least part of a corresponding one of the first electrodes 410 is located within a corresponding one of the pixel openings 220. The touch electrodes 420 are located on a side of the conductive portion 310 away from the substrate 100. The first electrodes 410 are insulated and spaced apart from the touch electrodes 420. The first electrodes 410 are insulated and spaced apart from the conductive portion 310. A corresponding one of the touch electrodes 420 and the conductive portion 310 are electrically connected to each other.

In the display panel provided in this embodiment of the present application, the display panel includes the substrate 100, the pixel define layer 200, the isolation structure 300, and the functional layer 400. The pixel define layer 200 includes the pixel defining portion 210 and the pixel openings 220, and a corresponding one of the pixel openings 220 is used to arrange a light-emitting unit 230 to implement the luminous display of the display panel. The functional layer 400 includes the first electrodes 410 and the touch electrodes 420. At least part of a corresponding one of the first electrodes 410 is located within a corresponding one of the pixel openings 220 to drive the light-emitting unit 230 to emit light. The touch electrodes 420 are arranged on the conductive portion 310, such that the isolation structure 300 can isolate the touch electrodes 420 from the first electrodes 410, and the first electrodes 410 and the touch electrodes 420 are less prone to short-circuit connection. A corresponding one of the touch electrodes 420 and the conductive portion 310 are electrically connected to each other, which can reduce the impedance of the touch electrode 420, improve the touch effect of the display panel, and also alleviate the impact of the parasitic capacitance formed between the conductive portion 310 and the touch electrode 420 on the normal operation of the touch electrode 420. By arranging the touch electrodes 420 and the first electrodes 410 in the same functional layer 400, the present application can simplify the structure and preparation process of the display panel.

Optionally, the substrate 100 may include a substrate base and an array substrate. The array substrate may include a drive circuit. For example, the array substrate may include a first signal line layer, a second signal line layer, and a third signal line layer that are arranged on a side of the substrate base and that are stacked. An insulation layer is provided between adjacent signal line layers. For example, a pixel driving circuit arranged on the array substrate includes a transistor and a storage capacitor. The transistor includes a semiconductor, a gate, a source, and a drain. The storage capacitor includes a first plate and a second plate. As an example, the gate and the first plate may be located in the first signal line layer, the second plate may be located in the second signal line layer, and the source and the drain may be located in the third signal line layer.

Optionally, during the preparation of the display panel, a functional material layer may be deposited on the isolation structure 300 and the pixel define layer 200. A part falling outside the isolation structure 300 forms a first electrode 410, and a part falling on the isolation structure 300 forms a touch electrode 420, such that the first electrode 410 and the touch electrode 420 can be prepared and formed in the same process step, thereby simplifying the preparation process of the display panel.

In some optional embodiments, the isolation structure 300 further includes an insulation portion 320. The insulation portion 320 includes a communication opening 321 and a first section 322 located on the side of the conductive portion 310 away from the substrate 100. The first section 322 is arranged around at least part of the communication opening 321, and a corresponding one of the touch electrodes 420 and the conductive portion 310 are electrically connected to each other via the communication opening 321.

In these optional embodiments, the isolation structure 300 further includes the insulation portion 320 located on the side of the conductive portion 310 away from the substrate 100, which can enable the first electrodes 410 to be better insulated from the touch electrodes 420 through the isolation structure 300. The insulation portion 320 includes the communication opening 321 and the first section 322. The communication opening 321 can enable the touch electrodes 420 and the conductive portion 310 to be electrically connected to each other, and the first section 322 can ensure that the first electrodes 410 are insulated from the touch electrodes 420.

The insulation portion 320 is provided in a variety of materials, for example, the insulation portion 320 may include an organic insulation layer and/or an inorganic insulation layer, i.e., the material of the insulation portion 320 may include an organic insulating material and/or an inorganic insulating material.

Optionally, the display panel further includes a carrier layer, where the carrier layer is located on a side of the pixel define layer 200 away from the substrate 100, and at least part of the insulation portion 320 and the carrier layer are made of a same material. The carrier layer may be configured in a variety of ways. For example, the carrier layer includes at least one of a hole injection layer, a hole transport layer, an electron blocking layer, a hole blocking layer, an electron transport layer, or an electron injection layer.

In these optional embodiments, at least part of the insulation portion 320 and the carrier layer are made of the same material, such that the insulation portion 320 and the carrier layer may be prepared and formed in the same process step. For example, during the preparation of the carrier layer, at least part of the material of the carrier layer falls on the conductive portion 310 to form the insulation portion 320, which can simplify the preparation process of the display panel.

Optionally, there are a plurality of communication openings 321. The same touch electrode 420 and the conductive portion 310 are electrically connected to each other via the plurality of communication openings 321, which can increase a contact area between the touch electrode 420 and the conductive portion 310, and better reduce the impedance of the touch electrode 420.

The communication openings 321 may be arranged in a variety of locations. In some optional embodiments, still referring to FIGS. 1 and 2, an orthographic projection of a corresponding one of the communication openings 321 on the substrate 100 is arranged adjacent to an area enclosed by an orthographic projection of the first section 322 on the substrate 100. That is, the communication opening 321 may be arranged outside the first section 322. During the preparation of the first section 322, for example, when the first section 322 is prepared by using a mask or the like, a location of the communication opening 321 can be reserved without depositing material, to form the first section 322.

The communication opening 321 can be formed without patterning the first section 322, which can simplify the preparation process of the display panel.

In some optional embodiments, the display panel includes an active area AA and a non-active area NA arranged around at least part of the active area AA. At least part of the touch electrode 420 and the conductive portion 310 extend from the active area AA to the non-active area NA. At least part of the first section 322 is located in the active area AA, and the communication opening 321 is located in the non-active area NA.

In these optional embodiments, at least part of the first section 322 is located in the active area AA, which can mitigate a problem that the touch electrodes 420 and the first electrodes 410 are prone to short-circuit connection in the active area AA. The communication opening 321 is located in the non-active area NA, so that the touch electrode 420 and the conductive portion 310 are electrically connected to each other in the non-active area NA.

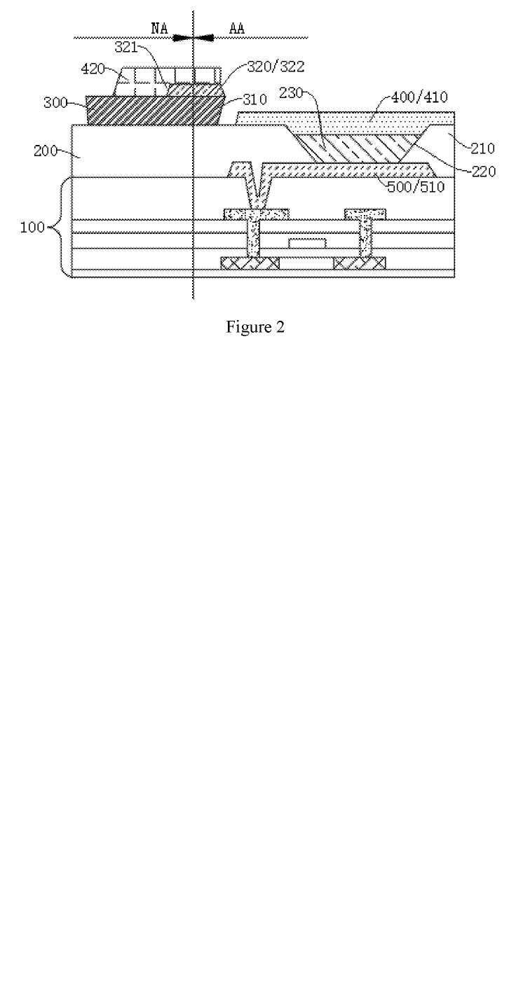

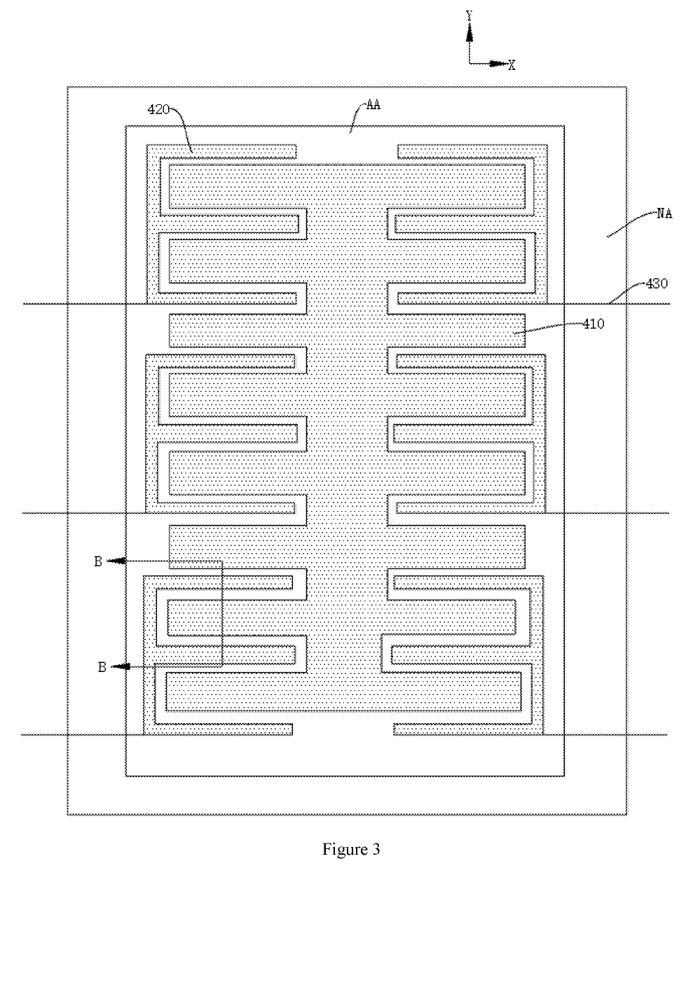

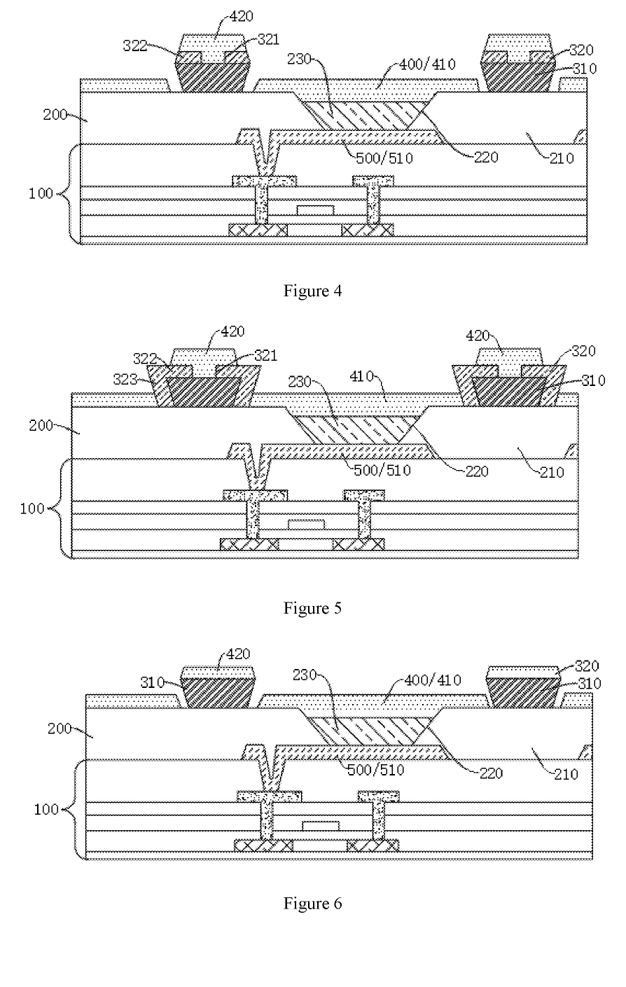

Referring to FIGS. 3 and 4 together, FIG. 3 is a schematic plan view of a display panel according to another embodiment of the present application; and FIG. 4 is a cross-sectional view along line B-B in FIG. 3.

In some other optional embodiments, as shown in FIGS. 3 and 4, the first section 322 is arranged around the communication opening 321, and an orthographic projection of the communication opening 321 on the substrate 100 is within an area enclosed by an edge of an orthographic projection of the first section 322 on the substrate 100. That is, the communication opening 321 runs through the first section 322, and the first section 322 encloses a closed communication opening 321.

In these optional embodiments, the communication opening 321 is enclosed by the first section 322. An arrangement location of the communication opening 321 is more flexible, which facilitates an electrical connection between the touch electrode 420 and the conductive portion 310.

Optionally, as described above, the display panel includes the active area AA and the non-active area NA. The communication opening 321 may be located in the active area AA of the display panel. The communication opening 321 is located in the active area AA, so that the touch electrode 420 and the conductive portion 310 may be electrically connected to each other in the active area AA, which can shorten a connection distance between the touch electrode 420 and the conductive portion 310, and better reduce the impedance of the touch electrode 420.

Optionally, as shown in FIG. 5, the insulation portion 320 further includes a second section 323 connected to the first section 322 and extending towards the substrate 100. The first section 322 and the second section 323 enclose a receiving groove communicating with opening 321 facing the substrate 100, and the conductive portion 310 is located in the receiving groove.

In these optional embodiments, the insulation portion 320 includes the first section 322 and the second section 323. The second section 323 extends from the first section 322 towards the substrate 100. The second section 323 and the first section 322 enclose the receiving groove. The conductive portion 310 is located in the receiving groove, such that the insulation portion 320 can provide protection in different directions to the conductive portion 310, making the first electrodes 410 and the conductive portion 310 less prone to short-circuit connection.

Optionally, the conductive portion 310 includes a bottom surface facing the substrate 100, a top surface away from the substrate 100, and a side surface connecting the top surface to the bottom surface. The bottom surface of the conductive portion 310 is in contact with the substrate 100 or the pixel defining portion 210 for connection, and a part of the top surface and the side surface of the conductive portion 310 are in contact with the insulation portion 320 for connection, such that all surfaces of the conductive portion 310 can be insulated from the outside.

In some optional embodiments, the isolation structure 300 includes a first surface facing the substrate 100 and a second surface away from the substrate 100. An orthographic projection of the first surface on the substrate 100 is within an orthographic projection of the second surface on the substrate 100.

In these optional embodiments, a size of the first surface of the isolation structure 300 facing the substrate 100 is less than or equal to a size of the second surface of the isolation structure away from the substrate 100, so that a segment gap or a recessed structure can be formed on the side surface of the isolation structure 300. The first electrodes 410 and the touch electrodes 420 are likely to be disconnected from each other at an edge of the isolation structure 300, and thus insulated from each other.

Optionally, as shown in FIG. 5, when the insulation portion 320 wraps the conductive portion 310, the first surface is jointly formed by a surface of the second section 323 and a surface of the conductive portion 310 that face the substrate 100. The second surface may be arranged on the first section 322, such that the first electrodes 410 and the touch electrodes 420 are likely to be disconnected and insulated from each other at an edge of the insulation portion 320.

Optionally, as shown in FIG. 2, when the conductive portion 310 and the first section 322 of the insulation portion 320 are stacked, the conductive portion 310 includes a first bottom surface facing the substrate 100 and a first top surface away from the substrate, and an orthographic projection of the first bottom surface on the substrate 100 is within an orthographic projection of the first top surface on the substrate 100; and/or the first section 322 includes a second bottom surface facing the substrate 100 and a second top surface away from the substrate, and an orthographic projection of the second bottom surface on the substrate 100 is within an orthographic projection of the second top surface on the substrate 100. In this way, the first electrodes 410 and the touch electrodes 420 are likely to be disconnected at an edge of the conductive portion 310 and/or the first section 322, and thus insulated from each other.

In still other optional embodiments, as shown in FIG. 6, the conductive portion 310 and a corresponding one of the touch electrodes 420 are stacked on top of each other and are in contact with each other for connection, which can increase a contact area between the conductive portion 310 and the touch electrode 420, and further reduce the impedance of the touch electrode 420.

Optionally, the display panel further includes a carrier layer, where the carrier layer is located on a side of the pixel define layer 200 away from the substrate 100. A through hole runs through the carrier layer. An orthographic projection of the conductive portion 310 on the substrate 100 is within an orthographic projection of the through hole on the substrate 100. The touch electrode 420 and the conductive portion 310 are in contact with each other for connection in the through hole.

In these optional embodiments, when the display panel includes the carrier layer, the through hole may be provided on the carrier layer, so that the conductive portion 310 is exposed from the through hole, and the touch electrode 420 and the conductive portion 310 are in contact with each other for connection in the through hole, which can increase the contact area between the conductive portion 310 and the touch electrode 420, and further reduce the impedance of the touch electrode 420.

Optionally, as shown in FIGS. 2 to 6, a cross-sectional area of the conductive portion 310 decreases in a direction approaching the substrate 100, so that a recess may be formed on the side surface of the conductive portion 310, enabling the first electrodes 410 and the touch electrodes 420 to be likely to be disconnected at the edge of the conductive portion 310 and insulated from each other.

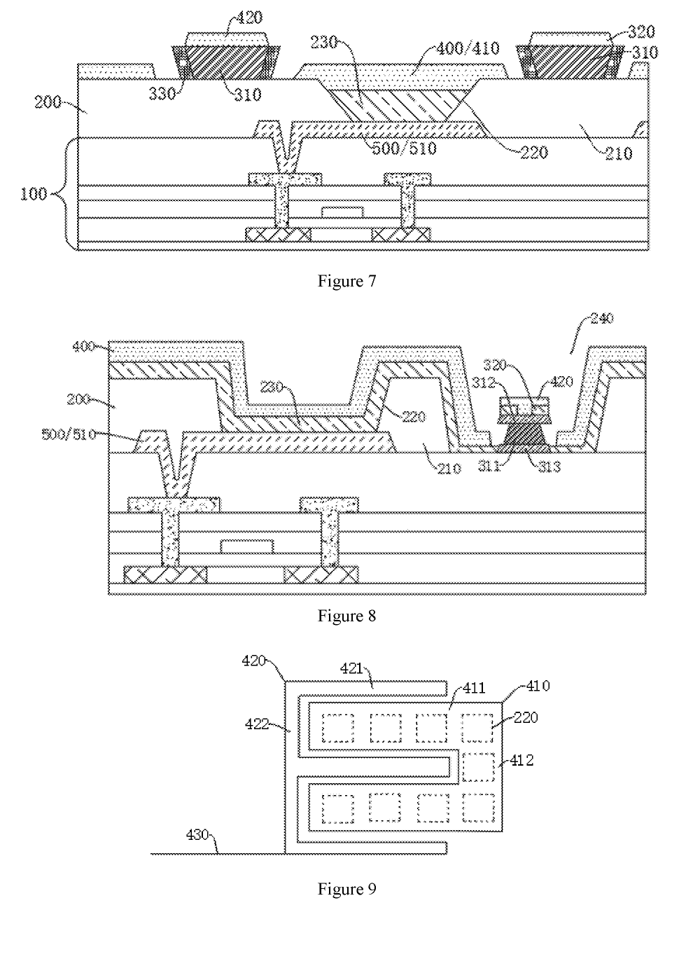

Optionally, as shown in FIG. 7, the conductive portion 310 includes a first bottom surface facing the substrate 100, a first top surface away from the substrate 100, and a first side surface connecting the first top surface to the first bottom surface. At least part of the first side surface is covered with an insulation layer 330, making it difficult for the first electrodes 410 to come into contact with the first side surface, which can mitigate the short-circuit connection between the first electrodes 410 and the conductive portion 310.

Optionally, as shown in FIG. 8, the conductive portion 310 includes a first sub-layer 311 and a second sub-layer 312 located on a side of the first sub-layer 311 away from the substrate 100. An orthographic projection of the first sub-layer 311 on the substrate 100 is within an orthographic projection of the second sub-layer 312 on the substrate 100. That is, a size of the first sub-layer 311 is less than or equal to a size of the second sub-layer 312, so that a segment gap or a recess can be formed on the side surface of the conductive portion 310, enabling the first electrodes 410 and the touch electrodes 420 to be likely to be disconnected at an edge of the conductive portion 310 and insulated from each other.

Optionally, the conductive portion 310 further includes a third sub-layer 313 located on a side of the first sub-layer 311 facing the substrate 100. Optionally, the orthographic projection of the first sub-layer 311 on the substrate 100 is within an orthographic projection of the third sub-layer 313 on the substrate 100. By arranging the third sub-layer 313, protection can be provided to the pixel defining portion 210 or the substrate 100 during the preparation of the first sub-layer 311.

In some optional embodiments, as shown in FIG. 9, each of the touch electrodes 420 includes first touch portions 421 and a second touch portion 422. The first touch portions 421 are formed by extending in a first direction X, a plurality of first touch portions 421 are spaced apart in a second direction Y, the second touch portion 422 connects two adjacent ones of the first touch portions 421, and the first direction X intersects the second direction Y. Each of the first electrodes 410 includes first electrode portions 411 and a second electrode portion 412. A corresponding one of the first electrode portions 411 is located between two adjacent ones of the first touch portions 421, a plurality of first electrode portions 411 are spaced apart in the second direction Y, and the second electrode portion 412 connects two adjacent ones of the first electrode portions 411.

In these optional embodiments, the touch electrode 420 includes the first touch portions 421 and the second touch portion 422. The second touch portion 422 is configured to connect adjacent first touch portions 421, such that the touch electrode 420 is comb-shaped. The second electrode portion 412 is configured to connect adjacent first electrode portions 411, and the first electrode 410 is comb-shaped as a whole. A corresponding one of the first electrode portions 411 is located between adjacent first touch portions 421, enabling the first electrodes 410 and the touch electrodes 420 to interdigitate with each other. This enables the touch electrodes 420 and the first electrodes 410 to be arranged at different locations in the active area AA, and can also ensure that the touch electrodes 420 and the first electrodes 410 are insulated from each other.

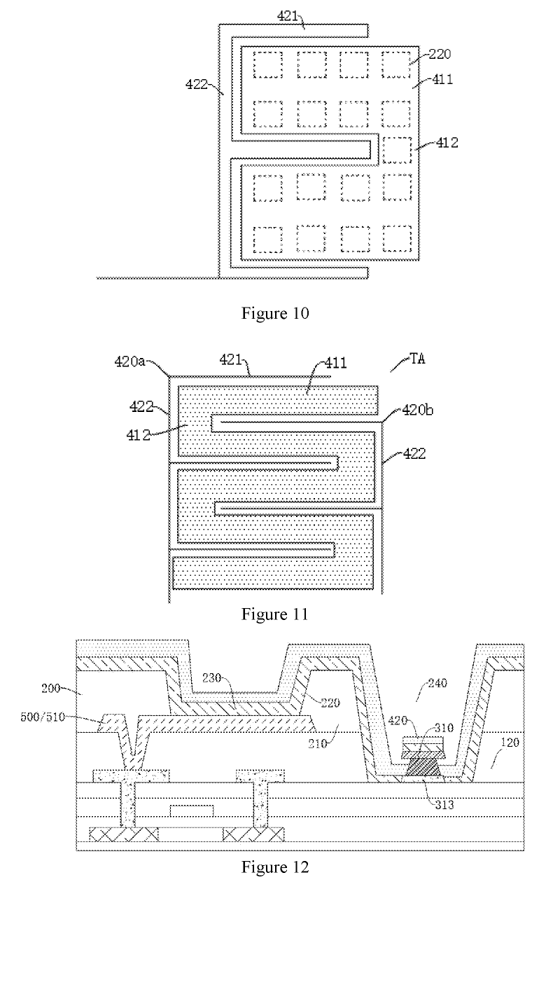

Optionally, as shown in FIGS. 9 and 10, at least one row of pixel openings 220 is correspondingly provided between two adjacent first touch portions 421, and the first direction X is a row direction. This enables the first electrode portion 411 located between the two adjacent first touch portions 421 to drive light-emitting units 230 within the at least one row of pixel openings 220 to emit light.

Optionally, shapes and sizes of the isolation structure 300 and the touch electrode 420 are adapted to each other. For example, the isolation structure 300 is arranged based on the shape of the touch electrode 420, and the isolation structure 300 is configured to support the touch electrode 420. Optionally, the isolation structure 300 includes first isolation portions configured to support the first touch portions 421 and a second isolation portion configured to support the second touch portion 422. The second isolation portion is configured to connect adjacent first isolation portions, such that the isolation structure 300 does not separate the first electrode 410 into independent first electrodes 410 corresponding to the pixel openings 220. First electrode portions 411 and second electrode portions 412 of the first electrodes 410 can communicate with each other to form a continuous electrode.

The touch electrode 420 may be configured in a variety of ways. The touch electrode 420 may be a self-capacitive touch electrode 420 or a mutual-capacitive touch electrode 420. For example, as shown in FIG. 11, the touch electrode 420 is a mutual-capacitive touch electrode 420. The touch electrode 420 includes a first touch electrode 420a and a second touch electrode 420b. The first touch electrode 420a and the second touch electrode 420b each include first touch portions 421 and a second touch portion 422.

Optionally, when the touch electrode 420 is a mutual-capacitive touch electrode 420, at least among a first touch electrode 420a and a second touch electrode 420b that are adjacent, a first touch portion 421 of the first touch electrode 420a and a first touch portion 421 of the second touch electrode 420b are alternately distributed in the second direction Y.

In these optional embodiments, by enabling the first touch portion 421 of the first touch electrode 420a and the first touch portion 421 of the second touch electrode 420b to be alternately distributed in the second direction Y, both the first touch electrode 420a and the second touch electrode 420b may be arranged at different locations in the active area AA, enabling both the first touch electrode 420a and the second touch electrode 420b to be relatively evenly distributed at different locations in the active area AA.

Optionally, a first electrode portion 411 is provided between the first touch portion 421 of the first touch electrode 420a and the first touch portion 421 of the second touch electrode 420b that are adjacent. Optionally, at least part of the second electrode portion 412 is located on a side of the first touch portion 421 of the first touch electrode 420a away from the second touch portion 422, or at least part of the second electrode portion 412 is located on a side of the first touch portion 421 of the second touch electrode 420b away from the second touch portion 422, so as to connect the first electrode portion 411 between the first touch portion 421 of the first touch electrode 420a and the first touch portion 421 of the second touch electrode 420b that are adjacent.

Optionally, as shown in FIG. 11, the first electrode 410 is S-shaped. For example, a plurality of first electrode portions 411 are spaced apart in the second direction Y. Second electrode portions 412 adjacent in the second direction Y are separately arranged on two sides of the first electrode portion 411 in the first direction X and connect adjacent first electrode portions 411.

Optionally, first touch electrodes 420a and second touch electrodes 420b are distributed in an array in the first direction X and the second direction Y. One or more first touch electrodes 420a may be arranged in the second direction Y. One or more second touch electrodes 420b may be arranged corresponding to a same first touch electrode 420a. That is, the first touch portion 421 of the same first touch electrode 420a and first touch portions 421 of the one or more second touch electrodes 420b may be alternately distributed in the second direction Y.

In some optional embodiments, the touch electrode 420 is located in the active area AA of the display panel, and the touch electrode 420 is a self-capacitive touch electrode 420. The functional layer 400 further includes touch leads 430 connected to touch electrodes 420. The plurality of touch leads 430 extend to at least two sides of the active area AA of the display panel.

In these optional embodiments, the functional layer 400 further includes the touch leads 430 connected to the touch electrodes 420, such that the touch electrodes 420 can transmit touch signals through the touch leads 430. The plurality of touch leads 430 extend to the at least two sides of the active area AA of the display panel, such that the plurality of touch leads 430 can be relatively evenly distributed on the display panel, which can improve the display effect of the display panel.

Optionally, the isolation structure 300 may be arranged at a variety of locations on the substrate 100. For example, as shown in FIGS. 2 to 6, the isolation structure 300 may be arranged on a side of the pixel defining portion 210 away from the substrate 100. During the preparation of the display panel, after the pixel define layer 200 is prepared and formed, the isolation structure 300 can be further prepared on the pixel defining portion 210. The preparation method of the isolation structure 300 is simple and convenient.

In some other optional embodiments, as shown in FIG. 8, the isolation structure 300 may be directly arranged on a surface of the substrate 100. For example, the pixel define layer 200 is further provided with a isolation opening 240. The isolation opening 240 are enclosed by the pixel defining portion 210, and at least part of the substrate 100 is exposed from the isolation opening 240, such that the isolation structure 300 may be directly arranged on a part of the substrate 100 exposed from the isolation opening 240. Optionally, the isolation structure 300 and an inner wall surface of the pixel defining portion 210 facing the isolation opening 240 are spaced apart. This makes it difficult for the functional layer 400 to be continuous between the isolation structure 300 and the pixel defining portion 210, and the first electrodes 410 and the touch electrodes 420 are less prone to short-circuit connection.

Optionally, the display panel further includes a second electrode layer 500. The second electrode layer 500 is located on a side of the pixel define layer 200 facing the substrate 100. The second electrode layer 500 includes a plurality of second electrodes 510 spaced apart. An orthographic projection of each second electrode 510 on the substrate 100 at least partially overlaps with an orthographic projection of each pixel opening 220 on the substrate 100, and the second electrodes 510 and at least part of the conductive portion 310 are made of a same material.

In these optional embodiments, the second electrodes 510 and at least part of the conductive portion 310 are made of the same material, so that the second electrodes 510 and the conductive portion 310 may be prepared and formed in the same process step, which can further simplify the preparation process of the display panel.

Optionally, one of the first electrode 410 and the second electrode 510 serves as an anode and the other serves as a cathode to drive the light-emitting unit 230 to emit light. An embodiment of the present application is described by using an example in which the first electrode 410 is a cathode and the second electrode 510 is an anode.

In still other embodiments, as shown in FIG. 12, the substrate 100 includes a metal layer and an insulating dielectric layer 120 located between the metal layer 110 and the pixel define layer 200. The pixel defining portion 210 further encloses a isolation opening 240. The insulating dielectric layer 120 is provided with a clearance opening that is in communication with the isolation opening 240. The isolation structure 300 is located in the clearance opening and the isolation opening 240. The metal layer 110 and at least part of the conductive portion 310 are made of a same material, so as to simplify the preparation process of the display panel. The metal layer 110 may be at least one of the first signal line layer, the second signal line layer, and the third signal line layer described above, or the metal layer 110 may be a separate signal line layer. The insulating dielectric layer 120 may be a planarization layer, a gate insulating dielectric layer, or the like.

An embodiment of a second aspect of the present application further provides a display apparatus, including a display panel according to any one of the above-described embodiments of the first aspect. Since the display apparatus according to the embodiment of the second aspect of the present application includes the display panel according to any one of the above-described embodiments of the first aspect, the display apparatus according to the embodiment of the second aspect of the present application has the beneficial effects of the display panel according to any one of the above-described embodiments of the first aspect, which will not be repeated herein.

The display apparatus in the embodiments of the present application includes, but is not limited to, devices having a display function, such as a mobile phone, a personal digital assistant (PDA), a tablet computer, an e-book reader, a television, an access control system, a smart fixed-line telephone, or a console.

1. A display panel, comprising:
a substrate;
a pixel define layer arranged on the substrate, the pixel define layer comprising a pixel defining portion and a plurality of pixel openings enclosed by the pixel defining portion;
an isolation structure arranged on the substrate, the isolation structure comprising a conductive portion; and
a functional layer comprising a plurality of first electrodes and a plurality of touch electrodes, wherein at least part of a corresponding one of the first electrodes is located within a corresponding one of the pixel openings, the touch electrodes are located on a side of the conductive portion away from the substrate, the first electrodes are insulated and spaced apart from the touch electrodes, the first electrodes are insulated and spaced apart from the conductive portion, and a corresponding one of the touch electrodes and the conductive portion are electrically connected to each other.

2. The display panel according to claim 1, wherein the isolation structure further comprises an insulation portion, wherein the insulation portion comprises a communication opening and a first section located on the side of the conductive portion away from the substrate, the first section is arranged around at least part of the communication opening, and a corresponding one of the touch electrodes and the conductive portion are electrically connected to each other via the communication opening.

3. The display panel according to claim 2, wherein the display panel further comprises a carrier layer, wherein the carrier layer is located on a side of the pixel define layer away from the substrate, and at least part of the insulation portion and the carrier layer are made of a same material.

4. The display panel according to claim 2, wherein there are a plurality of communication openings, and the same touch electrode and the conductive portion are electrically connected to each other via the plurality of communication openings.

5. The display panel according to claim 2, wherein an orthographic projection of the communication opening on the substrate is arranged adjacent to an area enclosed by an orthographic projection of the first section on the substrate.

6. The display panel according to claim 5, wherein the display panel comprises an active area and a non-active area, wherein the non-active area is located on at least one side of the active area, at least part of the touch electrodes and the conductive portion extend from the active area to the non-active area, the first section is located in the active area, and the communication opening is located in the non-active area.

7. The display panel according to claim 2, wherein the first section is arranged around the communication opening, and an orthographic projection of the communication opening on the substrate is within an area enclosed by an edge of an orthographic projection of the first section on the substrate.

8. The display panel according to claim 7, wherein the communication opening is located in an active area of the display panel.

9. The display panel according to claim 7, wherein the insulation portion further comprises a second section connected to the first section and extending towards the substrate, the first section and the second section enclose a receiving groove communicating with opening facing the substrate, and the conductive portion is located in the receiving groove.

10. The display panel according to claim 7, wherein the isolation structure comprises a first surface facing the substrate and a second surface away from the substrate, wherein the first surface is arranged on a side, of the second section and the conductive portion, facing the substrate, the second surface is arranged on a side of the first section away from the substrate, and an orthographic projection of the first surface on the substrate is within an orthographic projection of the second surface on the substrate.

11. The display panel according to claim 2, wherein the first section and the conductive portion are stacked; and
the conductive portion comprises a first bottom surface facing the substrate and a first top surface away from the substrate, and an orthographic projection of the first bottom surface on the substrate is within an orthographic projection of the first top surface on the substrate; and the first section has a second bottom surface facing the substrate and a second top surface away from the substrate, and an orthographic projection of the second bottom surface on the substrate is within an orthographic projection of the second top surface on the substrate.

12. The display panel according to claim 1, wherein the conductive portion and the touch electrodes are stacked on top of each other and are in contact with each other for connection.

13. The display panel according to claim 12, wherein the display panel further comprises a carrier layer, wherein the carrier layer is located on a side of the pixel define layer away from the substrate, a plurality of through holes run through the carrier layer, an orthographic projection of the conductive portion on the substrate is within an orthographic projection of the through holes on the substrate, and the touch electrodes and the conductive portion are in contact with each other for connection in the through holes.

14. The display panel according to claim 12, wherein a cross-sectional area of the conductive portion decreases in a direction approaching the substrate, or the conductive portion comprises a first sub-layer and a second sub-layer located on a side of the first sub-layer away from the substrate, an orthographic projection of the first sub-layer on the substrate being within an orthographic projection of the second sub-layer on the substrate.

15. The display panel according to claim 12, wherein the conductive portion comprises a first bottom surface facing the substrate, a first top surface away from the substrate, and a first side surface connecting the first top surface to the first bottom surface, at least part of the first side surface being covered with an insulation layer.

16. The display panel according to claim 1, wherein each of the touch electrodes comprises first touch portion and a second touch portion, the first touch portion extending in a first direction, a plurality of first touch portions being spaced apart in a second direction, the second touch portion connecting two adjacent first touch portions, and the first direction intersecting the second direction; and
each of the first electrodes comprises first electrode portion and a second electrode portion, a corresponding one of the first electrode portions being located between two adjacent ones of the first touch portions, a plurality of first electrode portions being spaced apart in the second direction, and the second electrode portion connecting two adjacent ones of the first electrode portions.

17. The display panel according to claim 1, wherein the isolation structure is arranged on a side of the pixel defining portion away from the substrate; or
the substrate comprises a metal layer and an insulating dielectric layer located between the metal layer and the pixel define layer, wherein the pixel defining portion further encloses a isolation opening, the insulating dielectric layer is provided with a clearance opening that is in communication with a corresponding the isolation opening, a part of the isolation structure is located in the clearance opening and the isolation opening, and the metal layer and at least part of the conductive portion are made of a same material.

18. The display panel according to claim 1, wherein the pixel defining portion further encloses isolation openings, and the isolation structure is located in the isolation openings and is spaced apart from an inner wall surface of the pixel defining portion facing the isolation opening.

19. The display panel according to claim 18, further comprising: a second electrode layer, the second electrode layer being located on a side of the pixel define layer facing the substrate, and the second electrode layer comprising a plurality of second electrodes spaced apart, wherein an orthographic projection of each second electrode on the substrate at least partially overlaps with an orthographic projection of each pixel opening on the substrate, and the second electrodes and at least part of the conductive portion are made of a same material.

20. A display apparatus, comprising a display panel according to any one of claim 1.
